(19) United States
(12) Patent Application Publication
(10) Pub. No.: US 2026/0208223 A1
(43) Pub. Date: Jul. 23, 2026

(54) LIQUID ADHESION APPARATUS AND LIQUID ADHESION METHOD

(71) Applicant: LINTEC Corporation, Tokyo (JP)

(72) Inventor: Takuya HAYASAKA, Tokyo (JP)

(21) Appl. No.: 19/438,993

(22) Filed: Jan. 2, 2026

(30) Foreign Application Priority Data
Jan. 21, 2025 (JP) 2025-008606

(51) Int. Cl. B05C 11/10; B05C 3/18; B05C 3/20; B05C 13/02

(52) U.S. Cl. CPC B05C 11/101; B05C 3/18; B05C 3/20; B05C 11/1044; B05C 13/02

(57) ABSTRACT

A liquid adhesion apparatus that causes a liquid to adhere to an adherend surface of an adherend to which a pellicle film is to be attached, includes: a liquid storage unit that stores the liquid in a liquid storage portion including an opening; a liquid supply unit that supplies the liquid to the liquid storage portion; and a liquid adhesion unit that causes the liquid to adhere to the adherend surface by bringing the adherend surface of the adherend into contact with the liquid stored in the liquid storage portion, in which the liquid supply unit includes a controller that controls an amount of the liquid to be supplied to the liquid storage portion.

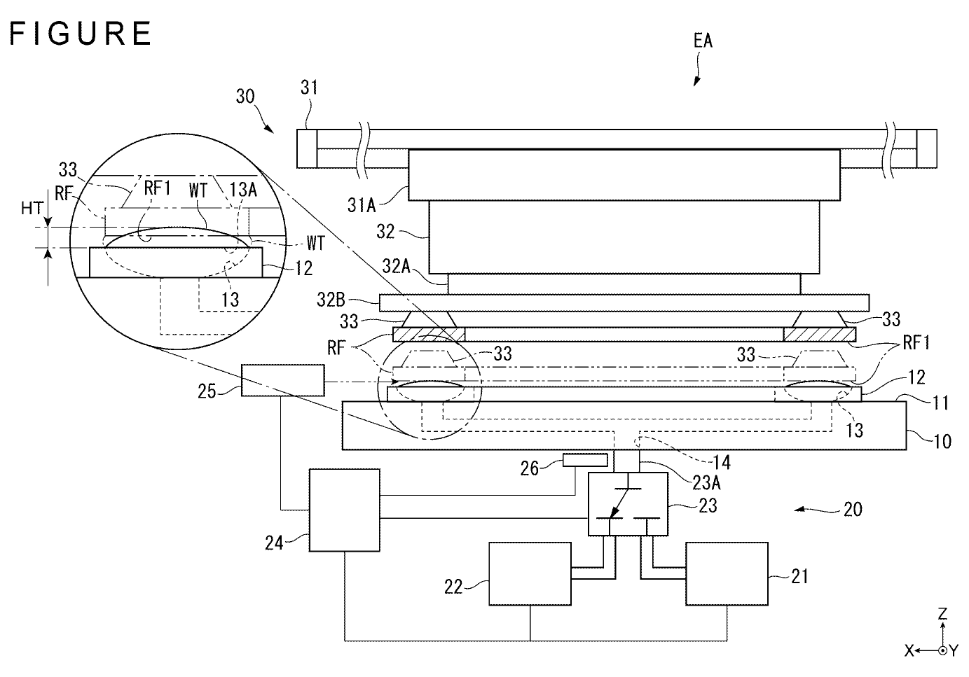

### CROSS REFERENCE TO RELATED APPLICATIONS

The entire disclosure of Japanese Patent Application No. 2025-008606 filed January 21, 2025 is expressly incorporated by reference herein.

### TECHNICAL FIELD

The present invention relates to a liquid adhesion apparatus and a liquid adhesion method.

### BACKGROUND ART

An apparatus is known that causes a liquid to adhere to an adherend surface of an adherend to which a pellicle film is to be attached (see, for example, Literature 1: JP2020-160345 A).

Literature 1 describes that water (liquid) is caused to adhere to a portion 190A (adherend surface) that comes into contact with a carbon nanotube self-supporting film 125 (pellicle film) of a frame-shaped member 190 (adherend). However, if the amount of the liquid is not appropriate, there is a problem in that the liquid may also adhere to portions other than the adherend surface of the adherend. The liquid adhering to portions other than the adherend surface may cause a situation in which the pellicle film may undesirably be attached to the portions other than the adherend surface due to the liquid adhering thereto.

### SUMMARY OF THE INVENTION

An object of the invention is to provide a liquid adhesion apparatus and a liquid adhesion method that are capable of preventing a liquid from adhering to portions other than an adherend surface of an adherend to which a pellicle film is to be attached.

An aspect of the invention employs a configuration set forth in the appended claims.

According to the aspect of the invention, the amount of the liquid to be supplied to a liquid storage portion is controlled to make the liquid amount suitable. It is thus possible to prevent the liquid from adhering to portions other than the adherend surface of the adherend to which the pellicle film is to be attached.

### BRIEF DESCRIPTION OF DRAWINGS

A figure illustrates a liquid adhesion apparatus according to an exemplary embodiment of the invention.

### DETAILED DESCRIPTION

Referring to the drawing, an exemplary embodiment of the invention will be described below.

An X-axis, a Y-axis, and a Z-axis in the exemplary embodiment are orthogonal to each other, in which the X-axis and the Y-axis are defined as axes in a predetermined plane and the Z-axis is defined as an axis perpendicular to the predetermined plane. In the exemplary embodiment, in a case where directions are defined as viewed from a near direction in the figure parallel to the Y-axis as a reference, "up" corresponds to an arrow direction of the Z-axis and "down" is the opposite direction thereto, "left" is an arrow direction of the X-axis and "right" is the opposite direction thereto, and "front" is the near direction in the figure parallel to the Y-axis and "rear" is the opposite direction thereto.

A liquid adhesion apparatus EA is an apparatus that causes water WT serving as a liquid to adhere to an adherend surface RF1 of a frame member RF serving as an adherend to which a sheet-shaped pellicle film formed from carbon nanotubes is to be attached. The liquid adhesion apparatus EA includes: a table 10 that serves as a liquid storage unit configured to perform a liquid storage step of storing the water WT in a groove 13, serving as a liquid storage portion, having an opening 13A; a liquid supply unit 20 configured to perform a liquid supply step of supplying the water WT to the groove 13; and a liquid adhesion unit 30 configured to perform a liquid adhesion step of bringing the adherend surface RF1 of the frame member RF into contact with the water WT stored in the groove 13 to cause the water WT to adhere to the adherend surface RF1.

In the exemplary embodiment, the frame member RF is configured including an annular metal member having a central opening.

The table 10 includes: an annular projection 12 provided on an upper surface portion 11; the circular groove 13 having the opening 13A opened in an upper surface of the projection 12; and a communication path 14 that communicates with the groove 13.

In the exemplary embodiment, the opening 13A has substantially the same size as the adherend surface RF1 of the frame member RF. The upper surface portion 11 and the projection 12 are coated with a water-repellent material such as an adhesive or a resin, and are thus liquiphobic, a property that makes the upper surface portion 11 and the projection 12 resistant to wetting and spreading of liquid.

The liquid supply unit 20 includes: a liquid feeding unit 21 configured to feed the water WT such as a pressure pump or a turbine; a waste liquid disposal unit 22 configured to discharge the water WT such as a decompression pump or a vacuum ejector; a switching valve 23 connected to the communication path 14 via a pipe 23A and configured to switch a communication state of the liquid feeding unit 21 and the waste liquid disposal unit 22 to the communication path 14; a controller 24 configured to control the amount of the water WT to be supplied to the groove 13 such as a personal computer or a sequencer; a sensing unit 25 including an imaging unit, such as a camera or a projector, configured to detect a swelling height HT of the water WT above the opening 13A, various sensors, such as an optical sensor or an ultrasonic sensor, and the like; and a liquid detection unit 26 configured to detect the water WT passing through the pipe 23A such as an optical sensor or an ultrasonic sensor.

The controller 24 is configured to control the amount of the water WT to be supplied to the groove 13 so that the water WT swells out of the opening 13A of the groove 13 due to surface tension.

The liquid adhesion unit 30 includes: a linear motor 31 serving as drive equipment; a linear motion motor 32 serving as drive equipment supported by a slider 31A of the linear motor 31; and a suction pad(s) 33 serving as a retaining member supported by an output shaft 32A of the linear motion motor 32 via a bracket 32B, with which the frame member RF can be retained by suction using a pressure reduction unit (not illustrated) such as a decompression pump or a vacuum ejector.

Operations of the liquid adhesion apparatus EA described above will be described.

First, a user of the liquid adhesion apparatus EA (hereinafter, referred to simply as "user") inputs, via a non-illustrated operation unit such as an operation panel or a personal computer, a signal for starting automatic operation to the liquid adhesion apparatus EA, the components of which are placed at respective initial positions illustrated by solid lines in the figure. Subsequently, the user or non-illustrated conveyance unit such as an articulated robot or a belt conveyor causes the frame member RF to abut against the suction pad 33. The liquid adhesion unit 30 then drives the non-illustrated pressure reduction unit to start retaining the frame member RF by suction on the suction pad 33. After that, the controller 24 of the liquid supply unit 20 drives the switching valve 23 to cause the communication path 14 and the liquid feeding unit 21 to communicate with each other and then drives the liquid feeding unit 21 to start the supply of the water WT to the groove 13. Subsequently, when the liquid detection unit 26 detects that the water WT passes through the pipe 23A, the controller 24 of the liquid supply unit 20 drives the liquid feeding unit 21 to reduce the flow rate of the water WT. Reducing the flow rate of the water WT after the detection of the water WT passing through the pipe 23A can shorten the time required for supplying the water WT to the groove 13 and prevent the water WT from overflowing from the groove 13. Then, as illustrated in the figure, when the sensing unit 25 senses that the water WT in the groove 13 swells out of the opening 13A due to surface tension and the swelling height HT of the water WT above the opening 13A reaches a desired value, the controller 24 of the liquid supply unit 20 stops the driving of the liquid feeding unit 21.

The liquid adhesion unit 30 then drives the linear motion motor 32 to move the frame member RF downward as illustrated by the two-dot chain lines in the figure, bringing the adherend surface RF1 into contact with the water WT swelling out of the opening 13A. The water WT is thus adhered to the adherend surface RF1. Then, the liquid adhesion unit 30 drives the linear motor 31 and the linear motion motor 32 to convey the frame member RF to the next step such as a pellicle film attachment step of attaching a pellicle film to the adherend surface RF1. Subsequently, the controller 24 of the liquid supply unit 20 drives the waste liquid disposal unit 22 and the switching valve 23 to cause the communication path 14 and the waste liquid disposal unit 22 to communicate with each other and the water WT remained in the groove 13 is discharged. Thereafter, the same steps as described above are repeated.

According to the exemplary embodiment as described above, the amount of the water WT to be supplied to the groove 13 is controlled to make the amount of the water WT suitable. It is thus possible to prevent the water WT from adhering to a portion other than the adherend surface RF1 of the frame member RF to which the pellicle film is to be attached.

The best configuration, method, and the like for carrying out the invention are disclosed in the above description. The invention, however, is not limited thereto. Thus, although the invention is particularly illustrated and described primarily with respect to a specific exemplary embodiment, those skilled in the art may make various modifications to the above exemplary embodiment in terms of shape, material, numerical quantity, and other detailed configurations without departing from the technical idea and the scope of the object of the invention. Further, the descriptions limiting the shapes, materials, and the like disclosed hereinabove are given as examples to facilitate understanding of the invention and are not intended to limit the invention. Therefore, descriptions in which components are named without some or all of the limitations on shape, material, and the like are within the scope of the invention.

Moreover, the units and steps in the invention are by no means limited as long as the operations, functions, or steps described in connection with the units and steps are achievable, and are in no way limited to the merely exemplary components or steps described in the above exemplary embodiment. For example, the liquid adhesion unit may be any unit capable of bringing the adherend surface of the adherend into contact with the liquid stored in the liquid storage portion and causing the liquid to adhere to the adherend surface, and is by no means limited insofar as being, in light of common technical knowledge in the art at the time of the filing the present application, within a technical scope of the knowledge (the same applies to any other units and steps).

The upper surface portion 11 of the table 10 may not be liquiphobic. The groove 13 may be provided in the upper surface portion 11 without the projection 12. The liquid storage portion may be constituted by intermittent grooves or recesses. The opening 13A may be formed smaller or larger than the adherend surface RF1 of the frame member RF.

The liquid supply unit 20 may or may not include the sensing unit 25 or the liquid detection unit 26. If the sensing unit 25 is not provided, the flow rate of the water WT passing through the pipe 23A may be detected by the liquid detection unit 26, and when the total amount of the water WT passing through the pipe 23A exceeds a predetermined value, the driving of the liquid feeding unit 21 may be stopped. If the liquid detection unit 26 is not provided, the flow rate of the water WT may be decreased after a predetermined time has passed following the start of the supply of the water WT, the supply amount of the water WT may be gradually decreased since the supply of the water WT has started, or the water WT may be supplied to the groove 13 so as not to swell out of the opening 13A.

The liquid adhesion unit 30 may control the height of the adherend surface RF1 relative to the opening 13A when the frame member RF is lowered, by changing a descent amount of the frame member RF retained by suction on the suction pad 33 based on the swelling height HT of the water WT above the opening 13A. Alternatively, the liquid adhesion unit 30 may move the table 10 while or without moving the frame member RF retained by suction on the suction pad 33 and cause the water WT to adhere to the adherend surface RF1.

Regarding the liquid configured to adhere to the adherend surface RF1, any liquid may be used with the characteristics, qualities, properties, materials, compositions, and configurations of the frame member RF and the adherend surface RF1 and the characteristics, qualities, properties, materials, compositions, configurations, and the like of the pellicle film taken into consideration, insofar as the liquid enables the pellicle film to be attached to the adherend surface RF1. For example, the liquid may be a polar solvent such as a low-molecular alcohol (e.g., isopropyl alcohol, methanol, and ethanol), a mixed solvent of the water WT and an organic solvent, or a molten metal such as solder, lead, tin, iron, and copper, in addition to an adhesive, resin, varnish, paint, and the like. In particular, in terms of letting no material other than the pellicle film remain on the adherend surface RF1, the liquid preferably consists of a component evaporable or volatilizable by heat or air drying, and the liquid is preferably the water WT, an organic solvent, or a mixed solvent thereof.

In the liquid adhesion apparatus EA, the liquid supply unit 20 may supply the water WT to the groove 13 after the liquid adhesion unit 30 moves the frame member RF downward. Alternatively, the liquid adhesion apparatus EA may include an affinity improvement treatment unit configured to perform, on the adherend surface RF1, an affinity improvement treatment of irradiating the adherend surface RF1 with plasma to improve an affinity for a liquid before the liquid adhesion unit 30 causes the liquid to adhere to the adherend surface RF1. It is preferred that the affinity improvement treatment refers to a treatment by which a contact angle of the liquid to the adherend surface RF1 after the affinity improvement treatment is lower than that before the affinity improvement treatment.

The frame member RF may be formed, for example, from metal such as stainless steel, aluminum, copper, or brass, resin such as silicone, fluorine resin, or acrylic resin, or a ceramic material. Silicon or quartz with a low thermal expansion coefficient is preferred. Silicon that is easy to be machined into a desired shape is more preferably used. The shape may be a non-annular shape (a shape having a discontinuous circumference), a circle, an oval, a polygon, or any other shape.

The material, type, shape, and the like of the adherend and the pellicle film in the invention are not particularly limited. For example, the adherend and the pellicle film may be in a shape of a circle, an oval, or a polygon such as a triangle or a quadrangle, or in any other shape.

Regarding the drive equipment of the above exemplary embodiment, motorized equipment such as a rotary motor, a linear motion motor, a linear motor, a single-axis robot, or a so-called articulated robot having biaxial or tri- or more axial joints, an actuator such as an air cylinder, a hydraulic cylinder, a rodless cylinder, or a rotary cylinder, and the like, may be used alone, or provided by a direct or indirect combination. Or, one capable or incapable of performing a torque control, a speed control, or the like on an output section of the motorized equipment, the actuator, or the like may be used.

In the above exemplary embodiment, an object (hereinafter, referred to as "object A") and another object (hereinafter, referred to as "object B") movable with respect to the object A, that is, relatively movable object A and object B may be defined as follows. The object B may be moved with respect to the immovable object A, the object A may be moved with respect to the immovable object B, or both the object A and the object B may be moved. It does not matter which one of the object A and the object B is to be moved insofar as the movement achieves the same result. In a case where there is provided an element, such as a support (retaining) unit or a support (retaining) member, that supports (retains) a member to be supported (a member to be retained), the member to be supported may be supported (retained) by a holder such as a mechanical chuck or a chuck cylinder, Coulomb force, an adhesive (an adhesive sheet or an adhesive tape), a sticky agent (a sticky sheet or a sticky tape), magnetic force, Bernoulli suction, suction adsorption, drive equipment, or the like.

What is claimed is:

1. A liquid adhesion apparatus configured to cause a liquid to adhere to an adherend surface of an adherend to which a pellicle film is to be attached, the apparatus comprising:
a liquid storage unit configured to store the liquid in a liquid storage portion including an opening;
a liquid supply unit configured to supply the liquid to the liquid storage portion; and
a liquid adhesion unit configured to cause the liquid to adhere to the adherend surface by bringing the adherend surface of the adherend into contact with the liquid stored in the liquid storage portion,
wherein the liquid supply unit includes a controller configured to control an amount of the liquid to be supplied to the liquid storage portion.

2. The liquid adhesion apparatus according to claim 1, wherein the controller is configured to control the amount of the liquid to be supplied to the liquid storage portion so that the liquid swells out of the opening of the liquid storage portion due to surface tension.

3. The liquid adhesion apparatus according to claim 2, wherein the liquid supply unit includes a sensing unit configured to sense a swelling height of the liquid above the opening.

4. A liquid adhesion method for causing a liquid to adhere to an adherend surface of an adherend to which a pellicle film is to be attached, the method comprising:
storing the liquid in a liquid storage portion including an opening;
supplying the liquid to the liquid storage portion; and
causing the liquid to adhere to the adherend surface by bringing the adherend surface of the adherend into contact with the liquid stored in the liquid storage portion,
wherein the supplying of the liquid includes controlling an amount of the liquid to be supplied to the liquid storage portion.
